(19) United States
(12) Patent Application Publication
(10) Pub. No.: US 2016/0053404 A1
(43) Pub. Date: Feb. 25, 2016

(54) CONTROLLABLE OXYGEN CONCENTRATION IN SEMICONDUCTOR SUBSTRATE

(71) Applicant: BEIJING TONGMEI XTAL TECHNOLOGY CO., LTD., Beijing (CN)

(72) Inventors: Morris YOUNG, Fremont, CA (US); Davis ZHANG, Fremont, CA (US); Vincent Wensen LIU, Beijing (CN); Yuanli WANG, Beijing (CN)

(21) Appl. No.: 14/780,280

(22) PCT Filed: Mar. 27, 2013
(86) PCT No.: PCT/CN2013/073260

§ 371 Date: Sep. 25, 2015

(51) Int. Cl. C30B 33/02; C30B 11/14; C30B 29/42; H01L 29/207; C30B 29/40; H01L 21/324; H01L 21/322; H01L 29/36; C30B 11/00; C30B 29/44

(52) U.S. Cl. CPC C30B 33/02; C30B 11/003; C30B 11/006; C30B 11/14; C30B 29/42; C30B 29/44; C30B 29/40; H01L 21/3245; H01L 21/3228; H01L 29/36; H01L 29/207

(57) ABSTRACT

A method of controlling oxygen concentration in III-V compound semiconductor substrate comprises providing a plurality of III-V crystal substrates in a container, providing a predetermined amount of material in the container. Atoms of the predetermined amount of material having a high chemical reactivity with oxygen atoms. The method further comprises maintaining a predetermined pressure within the container and annealing the plurality of III-V crystal substrates to yield an oxygen concentration in the crystal substrates. The oxygen concentration is associated with the predetermined amount of material.

### TECHNICAL FIELD

The example embodiments of the present invention generally relate to semiconductor fabrication, and more particularly to methods of controlling oxygen concentration in IIIA-VA compound semiconductor substrate.

BACKGROUND

Group IIIA-VA semiconductor compounds, such as gallium arsenide (GaAs), indium phosphide (InP) and gallium phosphide (GaP), are widely used in the manufacture of devices, such as microwave frequency integrated circuits, infrared light-emitting diodes, laser diodes, solar cells, high-power and high-frequency electronics, and optical systems. The device yield and performance characteristics of many products are dependent on the presence of trace impurities in the semiconductor process gases used in their manufacture. As a result, impurities may be doped in single crystal substrates. Through applied effort, ingenuity, and innovation, solutions to improve such systems and methods have been realized and are described in connection with embodiments of the present invention.

### SUMMARY

According to one exemplary embodiment of the present invention, a method of controlling oxygen concentration in III-V compound semiconductor substrate comprises providing a plurality of III-V crystal substrates in a container, and providing a predetermined amount of material in the container. Atoms of predetermined amount of material have high chemical reactivity with oxygen atoms in the container. The method further comprises maintaining a predetermined pressure within the container and annealing the plurality of III-V crystal substrates to yield an oxygen concentration in the crystal substrates. The oxygen concentration is associated with the predetermined amount of material.

According to one exemplary embodiment of the present invention, an III-V compound semiconductor substrate has a controllable oxygen concentration. The oxygen concentration is controlled by providing a plurality of III-V crystal substrates in a container, providing a predetermined amount of material in the container, and maintaining a predetermined pressure within the container and annealing the plurality of III-V crystal substrates to yield an oxygen concentration in the crystal substrates. The oxygen concentration of III-V crystal substrates is associated with the predetermined amount of material.

According to one exemplary embodiment of the present invention, a computer program product comprises a non-transitory computer readable storage medium and computer program instructions stored therein. The computer program instructions comprises program instructions configured to provide a plurality of III-V crystal substrates in a container, provide a predetermined amount of material in the container. Atoms of the predetermined amount of material have high chemical reactivity with oxygen atoms. The computer programmable instructions further comprise maintain a predetermined pressure within the container and anneal the plurality of III-V crystal substrates to yield an oxygen concentration in the single crystal substrates. The oxygen concentration of III-V crystal substrates is associated with the predetermined amount of material.

### BRIEF DESCRIPTION OF THE DRAWINGS

Having thus described the example embodiments of the present invention in general terms, reference will now be made to the accompanying drawings, which are not necessarily drawn to scale, and wherein:

FIG. 1 illustrates a method for controlling oxygen concentration in semiconductor substrates in accordance with some example embodiments;

FIG. 2 illustrates a sealed container with a plurality of crystal substrates and a predetermined amount of material having high chemical reactivity to oxygen atoms in accordance with some example embodiments;

FIG. 3 shows a table illustrating an example relationship between oxygen and carbon by weight;

FIG. 4 illustrates a graph showing an example relationship between oxygen and carbon weight in accordance with some example embodiments; and

FIG. 5 illustrates a schematic block diagram of circuitry that may be configured to control systems in accordance with some embodiments.

### DETAILED DESCRIPTION

The present disclosure now will be described more fully with reference to the accompanying drawings, in which some, but not all embodiments of the disclosure are shown. This disclosure may be embodied in many different forms and should not be construed as limited to the embodiments set forth; rather, these example embodiments are provided so that this disclosure will be thorough and complete, and will fully convey the scope of the disclosure to those skilled in the art. Like numbers refer to like elements throughout.

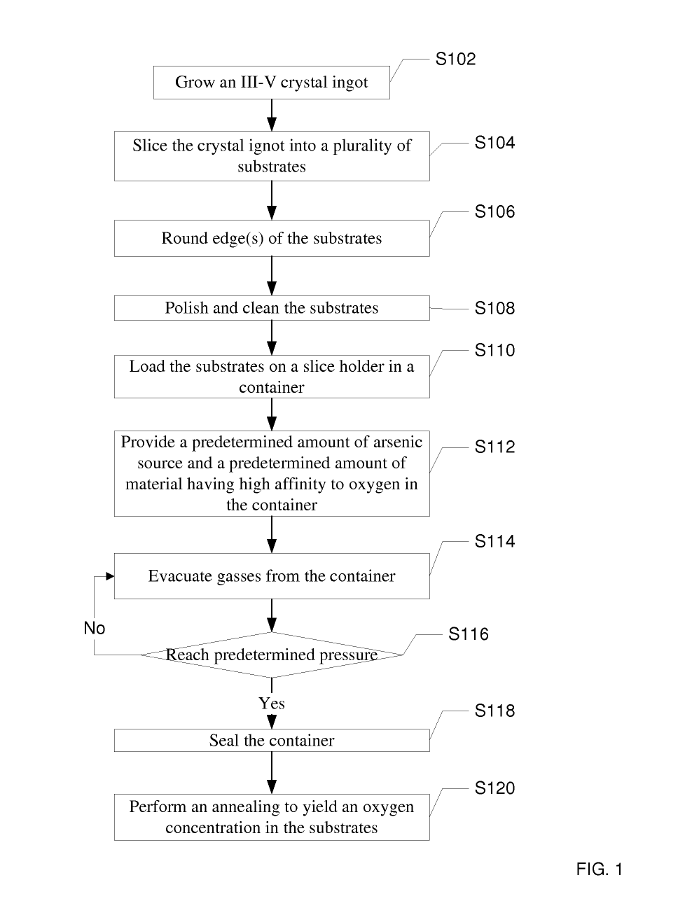

FIG. 1 illustrates an exemplary method for controlling oxygen concentration in III-V compound semiconductor substrates (“example,” “exemplary” and like terms as used herein refer to “serving as an example, instance or illustration”). To facilitate explanation of the invention, the description will be focused on the particular III-V compound semiconductor material Gallium Arsenide(“GaAs”),but the method (and/or aspects thereof)may be easily applied to or adapted for other chemicals, such as, e.g., Indium phosphide(InP), Gallium phosphide (GaP)and/or other materials used in manufacturing semi-conductor substrates and/or for any other purpose. For example, some embodiments may include both a GaAs crystal growth process (an example which is described below in more detail) and an annealing process (described in more detail below) to achieve the ability to control the oxygen concentration in a GaAs substrate being manufactured.

Referring to FIG. 1 at step S102, a crystal growth furnace may be used in accordance with some embodiments to grow one or more semi-insulating GaAs single crystal ingots using any suitable crystal-growth procedure, such as Vertical Gradient Freeze process, Vertical Bridgman process, Liquid Encapsulated Czochralski process, any other suitable crystal growth process, or a combination of crystal-growth processes. A grinding device may perform a grinding process to make each grown GaAs single crystal ingot into a cylindrical shape and/or any other form. For example, a crystal ingot grown at S102 may be formed into a cylindrical having a six-inch diameter and any suitable length. As such, at least one crystal growth furnace may be configured to perform at least some of the functions associated with S102 using any suitable approach to result in, for example, a III-V single crystal that may be sliced and/or otherwise modified to have a desired thickness, taper, bow, etc.

At S104, a slicing machine, such as an inner diameter saw slicing machine, may be used to slice each GaAs single crystal ingot into a plurality of substrates using various cutting techniques in accordance with some embodiments. The cutting techniques may include, for example, wire saw technology (e.g., slurry wire slicing and diamond wire slicing), abrasive fluid cutting techniques, inner diameter saw slicing, and/or any other suitable cutting techniques.

At S106, the edge(s) of the substrate(s) may be beveled and/or otherwise rounded using an edge grinder and/or other suitable machine. Edges without grinding or rounding typically exhibit a surface pattern formed during the slicing process of S104. Surface valleys may trap particles and impurities. These particles may be propagated to the substrate surface and increase the risk of substrate chipping. As such, an edge grinder and/or other suitable machine may be used to round the edges thereby minimizing the surface irregularities to prevent the edge(s) of the substrates from chipping, fragmenting and/or otherwise being damaged in the subsequent process.

At S108, polishing machine(s) may be configured to perform a polishing process to polish one or more surfaces of each substrate. The polishing process may include performing a rough polishing process to remove surface damage on the substrates and a final polishing process (e.g., a chemical mechanical polish) to flatten the surface of each substrate. The polishing process may further comprise using cleaning equipment that is configured to perform a clean process to clean at least some of the remaining particles and residues from the substrate surface(s). For example, the cleaning equipment may be configured to perform a cleaning process, such as a dry chemical cleaning process, a wet chemical cleaning process, and/or any other type of cleaning process. When wet chemical cleaning process is performed during the manufacturing of GaAs substrates, chemical solutions may be used. For example, the GaAs substrates may be immersed into a cleaning solution(such as, e.g., NH₄OH:H₂O₂:H₂O mixture in a ratio 1:2:9) and removed therefrom one or more times. The GaAs substrates may then be rinsed in a rinse system using, for example, de-ionized water.

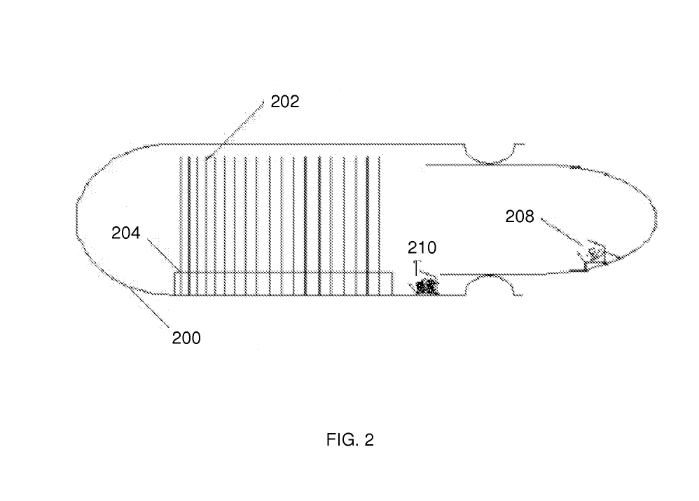

At S110, loading equipment, such as machines having tweezers-like components and/or other tools are used to load the sliced substrates on a substrate holder and then in a container. FIG. 2, for example, shows sliced substrates 202, substrate holder 204 and container 206. In some embodiments, substrate holder 204 may comprise a quartz boat. Container 206 may be a quartz tube, an ampoule or any other suitable containers.

At S112, to yield different levels of oxygen concentration in the GaAs and/or other type of substrate (s), a predetermined amount of material having high chemical reactivity with oxygen atoms, shown in FIG. 2 as material 210, may be provided into the container 206 The predetermined amount of material may have a large negative enthalpy of reaction with oxygen atoms, for example, −98.4 KJ/mol. The material 210 may comprise at least one of carbon with an enthalpy of reaction of −98.4 KJ/mol, aluminum with an enthalpy of reaction of −273.4 KJ/mol, titanium with an enthalpy of reaction of −228.2 KJ/mol, boron with an enthalpy of reaction of −210.6 KJ/mol, and/or any other material(s) having a large negative enthalpy of reaction with oxygen atoms. In an instance in which the substrate is GaAs, a predetermined amount of solid arsenic, shown in FIG. 2 as source 208, may be provided in the container, shown as the container 206. For example, source 208 may comprise 35 grams of solid arsenic source 208 and be placed in container 206 at S112. Material 210 may also or instead be provided at S112 in a predetermined amount, which may include a range of amounts. For example, the predetermined amount of material 210 may be any amount between zero and about 160 grams. The amount of material 210 introduced at S112 may aid in achieving a specific predetermined range of oxygen concentration during the annealing step(s).

At S114, air and other gasses in container 206 may be evacuated to a predetermined level of pressure by an evacuation system. The evacuation system may be a vacuum system, a pump, and/or any other devices that may evacuate gasses from container 206 until a predetermined pressure is reached. When the predetermined pressure (under approximately 10 torr) is reached at S116, container 206 may be sealed to maintain the predetermined pressure at S118.

At S120, container 206 and its contents, including sliced GaAs substrates 202, solid arsenic source 208 and material 210 may then be placed into an annealing furnace for annealing. The annealing furnace may be a horizontal-type annealing furnace, a vertical-type annealing furnace and/or any other types of annealing machines.

The annealing process may be optimized for heating rate, platform temperature, and/or cooling rate, among other things, to achieve controllable oxygen concentration. For example, the container may be heated at a heating rate of less than 100° C./hour. When a predetermined platform temperature (e.g., 1000° C. to 1100° C.) is reached, the platform temperature may be held constant for 10-20 hours in accordance with some embodiments. Subsequently, the temperature may be decreased and the container may be allowed to cool to room temperature (and/or any other suitable temperature) at a cooling rate of, for example, less than 100° C./hour. In some embodiments, heating and cooling may be conducted slowly to avoid warping/cracking that may otherwise result from thermal gradients and/or thermo-elastic stresses within the crystal substrates. The heating and cooling process may also prevent or otherwise aid in reducing defects due to frictions of crystal structures at the interface between the crystal and the container, and/or on surfaces of the substrates.

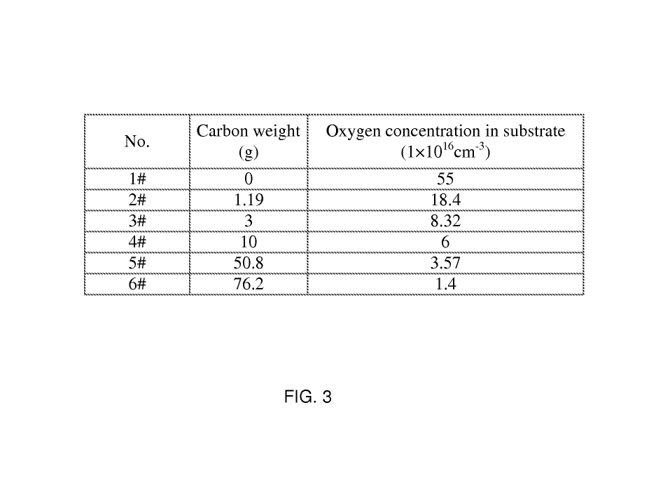

Once the substrates are annealed, a desired level of oxygen concentration may be achieved. The oxygen concentration in each substrate may vary with the amount of oxygen affinity material 210 introduced at S112. For example, Table 1 of FIG. 3 shows an example where carbon is provided as the oxygen affinity material 210, and different levels of oxygen concentration is achieved in the substrates by providing differing amounts of carbon. As shown in Table 1, when no carbon is provided, the oxygen concentration in the substrates has been found to be approximately 55×10¹⁶ atoms/cm⁻³. With an increase (by weight) of the carbon added at S112 as the material 210, the oxygen concentration generated by the method of FIG. 1 in the system of FIG. 2 may decrease. As another example, when about 76.2 grams of carbon is provided as the oxygen affinity material, the oxygen concentration in the substrate is approximately 1.4×10¹⁶ atoms/cm⁻³.

As a result of the annealing process, the substrate has light point defect density as low as less than 0.25/cm². Compared to the crystal ingot prior to the annealing process, the light point defect density is largely decreased. The light point defects of the ultra-clean substrates may be detected, for example, by KLA-Tencor 6220.

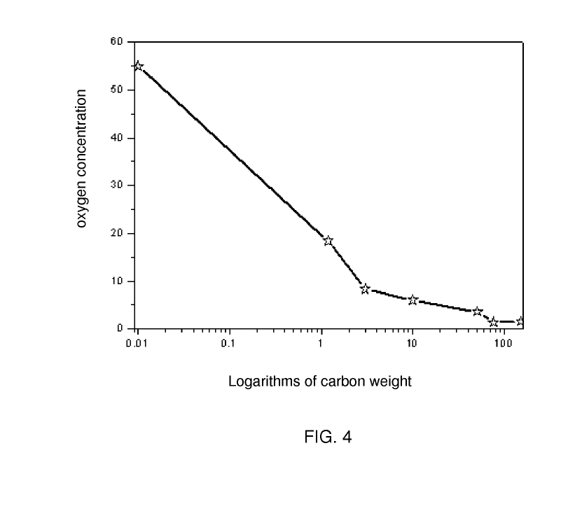

FIG. 4 illustrates a graph showing the relationship between oxygen concentration and logarithms of carbon weight based on table 1 of FIG. 3. As illustrated in FIG. 4, the oxygen concentration may change along with the carbon weight when used as the material 210. For example, by providing different amounts of carbon as the material 210, different levels of oxygen concentration are achieved in the substrates. Table 1 of FIG. 3, like the other drawings discussed herein, is in accordance with exemplary embodiments. Although carbon is used as the oxygen affinity material in these example embodiments, the oxygen affinity material is not limited to carbon and other oxygen affinity materials may be used as the material 210. Additionally, carbon weight of the material 210 may change within the range which may result in different levels of oxygen concentration.

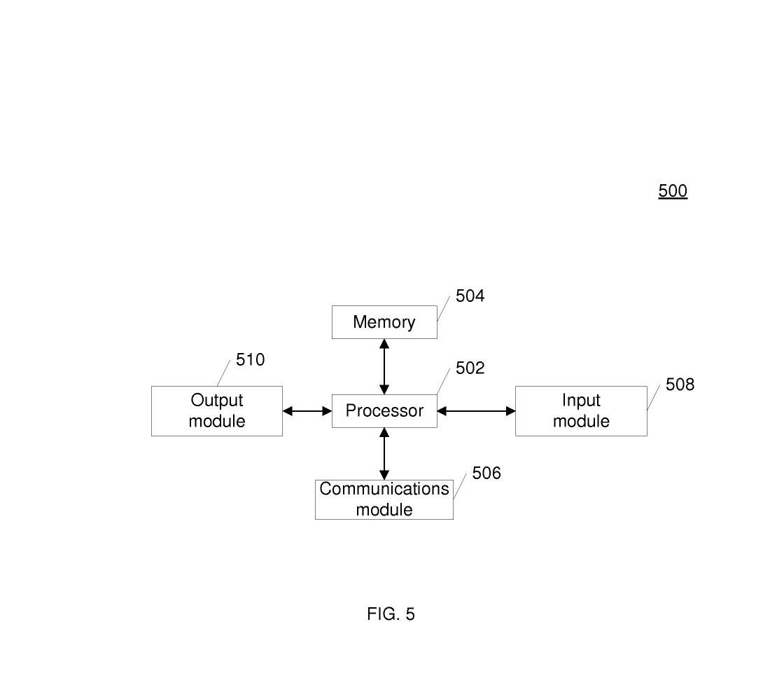

FIG. 5 shows a schematic block diagram of circuitry 500, some or all of which may be included in, for example, the crystal growth furnace, the slicing machine, the grinding device, the polishing machine, the loading station, the evacuation system and/or the annealing furnace. As illustrated in FIG. 5, in accordance with some example embodiments, the circuitry 500 may include various means, such as one or more processors 502, memories 504, communications modules 506, input modules 508 and/or output modules 510.

As referred to herein, “module” includes hardware, software and/or firmware configured to perform one or more particular functions. In this regard, the means of circuitry 500 as described herein may be embodied as, for example, circuitry, hardware elements (e.g., a suitably programmed processor, combinational logic circuit, and/or the like), a computer program product comprising computer-readable program instructions stored on a non-transitory computer-readable medium (e.g., memory 504) that is executable by a suitably configured processing device (e.g., processor 502), or some combination thereof.

Processor 502 may, for example, be embodied as various means including one or more microprocessors with accompanying digital signal processor(s), one or more processor(s) without an accompanying digital signal processor, one or more coprocessors, one or more multi-core processors, one or more controllers, processing circuitry, one or more computers, various other processing elements including integrated circuits such as, for example, an ASIC (application specific integrated circuit) or FPGA (field programmable gate array), or some combination thereof. Accordingly, although illustrated in FIG. 5 as a single processor, in some embodiments, processor 502 comprises a plurality of processors. The plurality of processors may be embodied on a single computing device or may be distributed across a plurality of computing devices collectively configured to function as circuitry 500. The plurality of processors may be in operative communication with each other and may be collectively configured to perform one or more functionalities of circuitry 500 as described herein. In an example embodiment, processor 502 is configured to execute instructions stored in memory 504 or otherwise accessible to processor 502. These instructions, when executed by processor 502, may cause circuitry 500 to perform one or more of the functionalities of circuitry 500 as described herein.

Whether configured by hardware, firmware/software methods, or by a combination thereof, processor 502 may comprise an entity capable of performing operations according to embodiments of the present invention while configured accordingly. Thus, for example, when processor 502 is embodied as an ASIC, FPGA or the like, processor 502 may comprise specifically configured hardware for conducting one or more operations described herein. As another example, when processor 502 is embodied as an executor of instructions, such as may be stored in memory 504, the instructions may specifically configure processor 502 to perform and/or control the equipment configured to perform one or more operations described herein, such as those discussed in connection with FIG. 1.

Memory 504 may comprise, for example, volatile memory, non-volatile memory, or some combination thereof. Although illustrated in FIG. 5 as a single memory, memory 504 may comprise a plurality of memory components. The plurality of memory components may be embodied on a single computing device or distributed across a plurality of computing devices. In various embodiments, memory 504 may comprise, for example, a hard disk, random access memory, cache memory, flash memory, a compact disc read only memory (CD-ROM), digital versatile disc read only memory (DVD-ROM), an optical disc, circuitry configured to store information, or some combination thereof. Memory 504 may be configured to store information (such as how much material 210 should be used), applications, instructions (such as how to communicate with and/or otherwise control various machines discussed in connection to FIG. 1), or the like for enabling circuitry 500 to carry out various functions in accordance with example embodiments of the present invention. For example, in at least some embodiments, memory 504 is configured to buffer input data for processing by processor 502. Additionally or alternatively, in at least some embodiments, memory 504 is configured to store program instructions for execution by processor 502. Memory 504 may store information in the form of static and/or dynamic information. This stored information may be stored and/or used by circuitry 500 during the course of performing its functionalities.

Communications module 506 may be embodied as any device or other type of means comprised of hardware, firmware, software or a combination thereof that is configured to receive and/or transmit data from/to another device, such as, for example, the circuitry 500, the machines discussed in connection with FIG. 1, and/or the like. In some embodiments, communications module 506 (like other components discussed herein) may be at least partially embodied as or otherwise controlled by processor 502. In this regard, communications module 506 may be in communication with processor 502, such as via a bus. Communications module 506 may include, for example, an antenna, a transmitter, a receiver, a transceiver, network interface card and/or supporting hardware and/or firmware/software for enabling communications with another computing device. Communications module 506 may be configured to receive and/or transmit any data that may be stored by memory 504 using any protocol that may be used for communications between computing devices. Communications module 506 may additionally or alternatively be in communication with the memory 504, input module 508 and output module 510 and/or any other component of circuitry 500, such as via a bus.

Input module 508 may be in communication with processor 502 to receive instructions from a sensor component by an audible, visual, mechanical, or other environmental stimuli. Input module 508 may include support, for example, for a keyboard, a mouse, a joystick, a display, a thermometer, pressure sensor, chemical sensor, light sensor, a touch screen display, a microphone, a speaker, a RFID reader, barcode reader, biometric scanner, and/or other input mechanisms. In some embodiments (like other components discussed herein), input module 508 may receive signals in response to changes in physical phenomena. For example, input module 508 as embodied in an annealing furnace may receive signals indicative of temperature changes from temperature sensors and then transmit the signals to processor 502. Input module 508 may be in communication with memory 504, communications module 506, and/or any other component(s), such as via a bus. Although more than one input module and/or other component may be included in circuitry 500, only one is shown in FIG. 5 to avoid overcomplicating the drawing (like the other components discussed herein).

Output module 510 may be in communication with processor 502 to perform instructions issued by processor 502 and stored in memory 504. The output module 510 may transmit signals, for example, position, temperature, pressure and/or other related signals to perform any step of or all steps of the method shown in FIG. 1. In accordance with exemplary embodiments, rather than utilizing communications module 506, output module 510 may control temperature, position, pressure and/or any other signals indicative of physical phenomenon of at least one of crystal growth furnace, slicing machine, grinding device, polishing machine, loading station, evacuation system, annealing furnace and/or other devices that facilitate the execution of the method described in FIG. 1.

As will be appreciated, any such computer program instructions and/or other type of code may be loaded onto a computer, processor or other programmable apparatus's circuitry to produce a machine, such that the computer, processor other programmable circuitry that execute the code on the machine create the means for implementing various functions, including those described herein.

Many modifications and other example embodiments set forth herein will come to mind to one skilled in the art to which these example embodiments pertain having the benefit of the teachings presented in the foregoing descriptions and the associated drawings. Therefore, it is to be understood that the embodiments are not to be limited to the specific ones disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions other than those explicitly described above are also contemplated as may be set forth in some of the appended claims. Although specific terms are employed herein, they are used in a generic and descriptive sense only and not for purposes of limitation.

What is claimed is:

1. A method of controlling oxygen concentration in III-V compound semiconductor substrate, comprising:
providing a plurality of III-V crystal substrates in a container;
providing a predetermined amount of material having high oxygen reactivity with oxygen atoms in the container;
maintaining a predetermined pressure within the container; and
annealing the plurality of III-V crystal substrates to yield an oxygen concentration in the crystal substrates, wherein the oxygen concentration is associated with the predetermined amount of material having high oxygen reactivity with oxygen atoms.

2. The method of claim 1, wherein the annealing further comprises heating the container to a platform temperature between 1000° C. and 1100° C. at a predetermined heating rate of less than 100° C./hour.

3. The method of claim 2, wherein the annealing further comprises maintaining the platform temperature for 10-20 hours.

4. The method of claim 1, wherein the annealing further comprises cooling the container at a predetermined cooling rate of less than 100° C./hour.

5. The method of claim 1, further comprising providing a predetermined amount of source material in the container

6. The method of claim 1, further comprising providing a predetermined amount of solid arsenic source in the container.

7. The method of claim 1, further comprising performing vertical gradient freeze process to grow an III-V crystal ingot.

8. The method of claim 1, further comprising rounding an edge of the III-V crystal substrates.

9. The method of claim 1, wherein providing the plurality of III-V crystal substrates in the container further comprises loading the plurality of III-V crystal substrates on a substrate holder and loading the substrate holder in the container.

10. The method of claim 1, wherein maintaining the container at the predetermined pressure further comprises evacuating the container and sealing the container to maintain the container at a pressure under approximately 10 torr.

11. The method of claim 1 further comprising slicing an III-V crystal ingot into the plurality of substrates.

12. The method of claim 1 further comprising cleaning the III-V crystal substrates by cleaning equipment.

13. A group III-V semiconductor substrate comprising oxygen concentration, the level of the oxygen concentration is controllable by providing material having high oxygen reactivity with oxygen atoms, wherein the oxygen concentration is controlled in a range between 1.2×10¹⁶ and 6×10¹⁷ atoms/cm⁻³.

14. The substrate of claim 13, wherein the material having a high chemical reactivity with oxygen atoms comprises at least one of carbon, aluminum, titanium and boron.

15. The semiconductor substrate of claim 13, wherein the substrate comprises one of GaAs, InP and GaP.

16. A III-V compound semiconductor substrate having a controllable oxygen concentration, the oxygen concentration is controlled by:
providing a plurality of III-V crystal substrates in a container;
providing a predetermined amount of material in the container, atoms of the predetermined amount of material having high chemical reactivity with oxygen atoms;
maintaining a predetermined pressure within the container; and
annealing the plurality of III-V crystal substrates to yield an oxygen concentration in the crystal substrates, wherein the oxygen concentration is associated with the predetermined amount of material having high oxygen reactivity.

17. A computer program product comprising a non-transitory computer readable storage medium and computer program instructions stored therein, the computer program instructions configured to control a processor to
provide a plurality of III-V crystal substrates in a container;
provide a predetermined amount of material in the container, atoms of the predetermined amount of material having high chemical reactivity with oxygen atoms;
maintain a predetermined pressure within the container; and
anneal the plurality of III-V crystal substrates to yield an oxygen concentration in the single crystal substrates, wherein the oxygen concentration is associated with the predetermined amount of material having high oxygen reactivity.
